(19) United States
(12) Patent Application Publication
(10) Pub. No.: US 2025/0357718 A1
(43) Pub. Date: Nov. 20, 2025

(54) LASER SYSTEM, LASER PROCESSING METHOD, AND INTERPOSER MANUFACTURING METHOD

(71) Applicant: Gigaphoton Inc., Tochigi (JP)

(72) Inventor: Takayuki OSANAI, Oyama-shi (JP)

(73) Assignee: Gigaphoton Inc., Tochigi (JP)

(21) Appl. No.: 19/174,451

(22) Filed: Apr. 9, 2025

(30) Foreign Application Priority Data
May 14, 2024 (JP) 2024-078978

(51) Int. Cl. H01S 3/091; H01S 3/094; H01S 3/108; H01S 3/109; H01S 3/16

(52) U.S. Cl. CPC H01S 3/0912; H01S 3/094038; H01S 3/1083; H01S 3/109; H01S 3/1666

(57) ABSTRACT

A laser system includes a pumping laser apparatus configured to output pumping light having a first wavelength; a signal laser apparatus configured to output signal light having a second wavelength longer than the first wavelength; an optical parametric crystal configured to transmit the pumping light and the signal light and output amplified light having the second wavelength; and a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

### CROSS-REFERENCE TO RELATED APPLICATIONS

The present application claims the benefit of Japanese Patent Application No. JP2024-078978, filed on May 14, 2024, the entire contents of which are hereby incorporated by reference.

### BACKGROUND

### 1. Technical Field

The present disclosure relates to a laser system, a laser processing method, and an interposer manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses undergoing spontaneous laser oscillation has a wide spectral linewidth ranging from 350 to 400 μm. A projection lens made of a material that transmits ultraviolet light, such as the KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] Japanese Patent No. 3,471,188
[PTL 2] WO2023/145524

### SUMMARY

A laser system according to an aspect of the present disclosure includes a pumping laser apparatus configured to output pumping light having a first wavelength; a signal laser apparatus configured to output signal light having a second wavelength longer than the first wavelength; an optical parametric crystal configured to transmit the pumping light and the signal light and output amplified light having the second wavelength; and a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

A laser processing method according to another aspect of the present disclosure includes generating laser light having a second wavelength by using a laser system, and converting the second wavelength of the laser light having to generate ultraviolet laser light; and irradiating a radiation receiving object with the ultraviolet laser light to process the radiation receiving object, the laser system including a pumping laser apparatus configured to output pumping light having a first wavelength, a signal laser apparatus configured to output signal light having the second wavelength longer than the first wavelength, an optical parametric crystal configured to transmit the pumping light and the signal light and output amplified light having the second wavelength, and a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

An interposer manufacturing method according to another aspect of the present disclosure includes generating laser light having a second wavelength by using a laser system, and converting the second wavelength of the laser light having to generate ultraviolet laser light; and irradiating a radiation receiving object with the ultraviolet laser light in order to manufacture an interposer, the laser system including a pumping laser apparatus configured to output pumping light having a first wavelength, a signal laser apparatus configured to output signal light having the second wavelength longer than the first wavelength, an optical parametric crystal configured to transmit the pumping light and the signal light and output amplified light having the second wavelength, and a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

### BRIEF DESCRIPTION OF DRAWINGS

Embodiments of the present disclosure will be described below only by way of example with reference to the accompanying drawings.

FIG. 1 schematically shows the configuration of a laser system according to Comparative Example.

FIG. 2 schematically shows the configuration of an optical parametric amplifier (OPA).

FIG. 3 schematically shows the configuration of a beam diameter adjusting optical system of the OPA.

FIG. 4 shows amplified light having a multi-ring profile.

FIG. 5 schematically shows the configuration of an OPA in a first embodiment.

FIG. 6 schematically shows the configuration of a beam power adjusting system of the OPA in the first embodiment.

FIG. 7 shows amplified light having a suppressed multi-ring profile.

FIG. 8 is a graph showing amplified light conversion efficiency in the form of a heat map.

FIG. 9 schematically shows the configuration of a laser processing system and an interposer processing apparatus according to a second embodiment.

FIG. 10 diagrammatically shows the configuration of an electronic device.

FIG. 11 is a flowchart showing a method for manufacturing the electronic device.

### DETAILED DESCRIPTION

### Contents

1. Laser system and amplification system according to Comparative Example
1.1 Overview of laser system
1.1.1 Configuration
1.1.2 Operation
1.2 Overview of amplification system
1.2.1 Configuration
1.2.2 Operation
1.2.3 Effects and advantages
2. Problems
3. First embodiment
3.1 Configuration
3.2 Operation
3.3 Derivation of conditions
3.4 Effects and advantages
4. Second embodiment
4.1 Configuration of laser processing system
4.2 Operation of laser processing system
5. Method for manufacturing electronic device including interposer
5.1 Example of configuration of electronic device
5.2 Electronic device manufacturing method
6. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Laser System and Amplification System According to Comparative Example

### 1.1 Overview of Laser System

### 1.1.1 Configuration

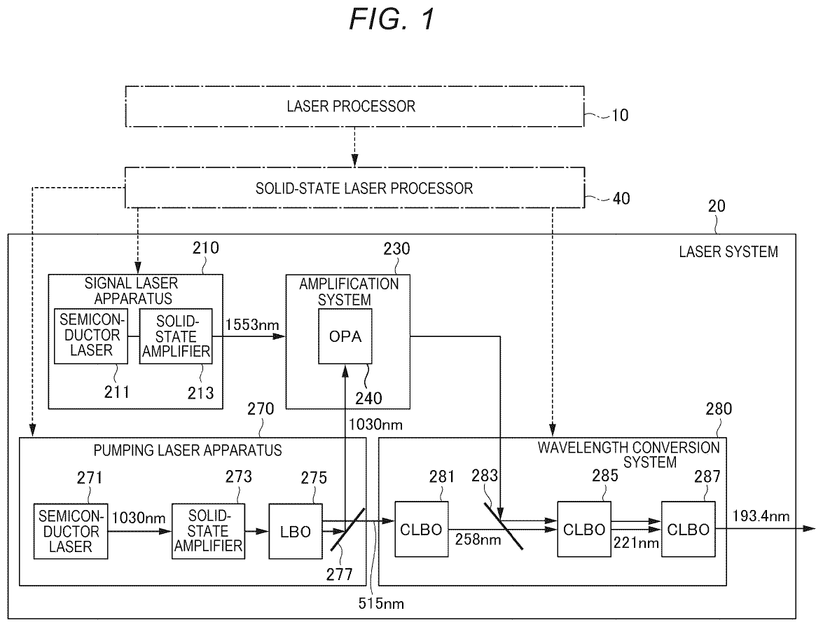

FIG. 1 schematically shows the configuration of a laser system 20 according to Comparative Example. Comparative Example in the present disclosure is an aspect that the applicant is aware of as known only by the applicant, and is not a publicly known example that the applicant is self-aware of.

The laser system 20 includes a signal laser apparatus 210, an amplification system 230, a pumping laser apparatus 270, and a wavelength conversion system 280. The laser system 20 outputs pulsed laser light having a wavelength of about 193.4 nm.

The signal laser apparatus 210 includes a semiconductor laser 211 and a solid-state amplifier 213. The semiconductor laser 211 performs CW (continuous wave) oscillation in a single longitudinal mode at a wavelength of about 1553 nm or about 1407 nm.

The solid-state amplifier 213 includes a semiconductor optical amplifier (SOA) that amplifies the CW-oscillation laser light output from the semiconductor laser 211.

The pumping laser apparatus 270 includes a semiconductor laser 271, a solid-state amplifier 273, an LBO crystal 275, which is a nonlinear optical crystal, and a dichroic mirror (DM) 277. The term “LBO” stands for a chemical formula LiB₃O₅.

The semiconductor laser 271 includes a semiconductor laser that performs CW oscillation in a single longitudinal mode at a wavelength of about 1030 nm or about 1064 nm. The solid-state amplifier 273 is an amplifier including an SOA that is not shown, and a Yb fiber amplifier or a Yb: YAG crystal.

The LBO crystal 275 converts the laser light having the wavelength of about 1030 nm in terms of wavelength into second harmonic light (having wavelength of about 515 nm). A description will be given about a case where the semiconductor laser 211 outputs laser light having the wavelength of about 1553 nm, and the semiconductor laser 271 outputs laser light having the wavelength of about 1030 nm. Note that even when the semiconductor laser 211 outputs laser light having the wavelength of about 1407 nm and the semiconductor laser 271 outputs laser light having the wavelength of about 1064 nm, the laser system 20 still outputs the pulsed laser light having the wavelength of about 193.4 nm.

The DM 277 is disposed in the optical path downstream from the LBO crystal 275, transmits the pulsed laser light having the wavelength of about 515 nm at high transmittance, and reflects the pulsed laser light having the wavelength of about 1030 nm at high reflectance. The pulsed laser light having the wavelength of about 1030 nm and reflected off the DM 277 at high reflectance enters the amplification system 230 as pumping laser light.

The amplification system 230 includes an optical parametric amplifier (OPA) 240. The OPA 240 is, for example, an amplifier including a periodically poled lithium niobate (PPLN) crystal or a periodically poled KTP (PPKTP) crystal. The OPA 240 receives the pumping laser light and signal laser light to pulse and amplify the signal laser light.

The wavelength conversion system 280 includes a DM 283 and CLBO crystals 281, 285, and 287, which are nonlinear optical crystals. The term “CLBO” stands for a chemical formula CsLiB₆O₁₀. The CLBO crystals 281, 285, and 287 are disposed on respective rotary stages that are not shown but each of which includes a piezoelectric device, and each configured to be capable of changing at high speed the angle of incidence of the pulsed laser light to be incident on the crystal.

The CLBO crystal 281 converts the second harmonic light (having wavelength of about 515 nm) in terms of wavelength into fourth harmonic light (having wavelength of about 258 nm).

The DM 283 is configured to reflect the pulsed laser light output from the amplification system 230 at high reflectance and transmit the pulsed laser light output from the CLBO crystal 281 at high transmittance, and is so disposed that the two types of pulsed laser light are coaxially incident on the CLBO crystal 285.

The CLBO crystals 285 and 287 are arranged in series, and perform sum-frequency generation twice to output pulsed laser light having the wavelength of about 193.4 nm.

The laser system 20 is controlled by a solid-state laser processor 40 and a laser processor 10. A processor in the present disclosure is a processing apparatus including a storage that stores a control program and a CPU (central processing unit) that executes the control program. The processor may include a GPU (graphics processing unit). The processor is particularly configured or programmed to carry out a variety of processes included in the present disclosure.

The solid-state laser processor 40 is connected to the signal laser apparatus 210, the pumping laser apparatus 270, and the wavelength conversion system 280. The laser processor 10 is connected to the solid-state laser processor 40. Note that the processing function of the solid-state laser processor 40 may be implemented in the laser processor 10.

### 1.1.2 Operation

The solid-state laser processor 40 controls the value of the current flowing through the semiconductor laser 271 of the pumping laser apparatus 270 to cause the semiconductor laser 271 to perform CW oscillation so as to output CW laser light having the wavelength of about 1030 nm. Furthermore, the solid-state laser processor 40 causes the SOA of the solid-state amplifier 273 to pulse the CW laser light, and causes the Yb fiber amplifier or the amplifier including a Yb: YAG crystal of the solid-state amplifier 273 to pulse and amplify the CW laser light.

The LBO crystal 275 converts the pulsed laser light having the wavelength of about 1030 nm into the second harmonic light having the wavelength of about 515 nm. The second harmonic light having the wavelength of about 515 nm passes through the DM 277 at high transmittance and enters the wavelength conversion system 280.

The DM 277 reflects the pulsed laser light having the wavelength of about 1030 nm and not having been converted in terms of wavelength by the LBO crystal 275 at high reflectance, and causes the reflected pulsed laser light to enter the OPA 240 as the pumping laser light for pumping the amplification system 230.

The solid-state laser processor 40 controls the value of the current flowing through the semiconductor laser 211 to cause the semiconductor laser 211 to output the CW laser light having the wavelength of about 1553 nm. Furthermore, the solid-state laser processor 40 causes the solid-state amplifier 213 to perform amplification and output amplified CW laser light having the wavelength of about 1553 nm from the signal laser apparatus 210.

The OPA 240 of the amplification system 230 receives the pulsed laser light having the wavelength of about 1030 nm and reflected off the DM 277 as the pumping laser light and the CW laser light having the wavelength of about 1553 nm and output from the signal laser apparatus 210 as the signal laser light to output amplified pulsed laser light having the wavelength of about 1553 nm.

First pulsed laser light output from the amplification system 230 and having the wavelength of about 1553 nm and second pulsed laser light output from the pumping laser apparatus 270 and having the wavelength of about 515 nm are input to the wavelength conversion system 280. The second pulsed laser light is converted by the CLBO crystal 281 into pulsed laser light that is ultraviolet light having the wavelength of about 258 nm. The CLBO crystal 285 then performs sum-frequency generation on the first pulsed laser light and the ultraviolet light having the wavelength of about 258 nm to convert the wavelength of the incident light into a wavelength of about 221 nm, and the CLBO crystal 287 then performs sum-frequency generation on the light having the wavelength of about 221 nm and the pulsed laser light having the wavelength of about 1553 nm to output the pulsed laser light having the wavelength of about 193.4 nm.

The generated pulsed laser light having the wavelength of about 193.4 nm may be amplified by an excimer amplifier that is not shown.

### 1.2 Overview of Amplification System

### 1.2.1 Configuration

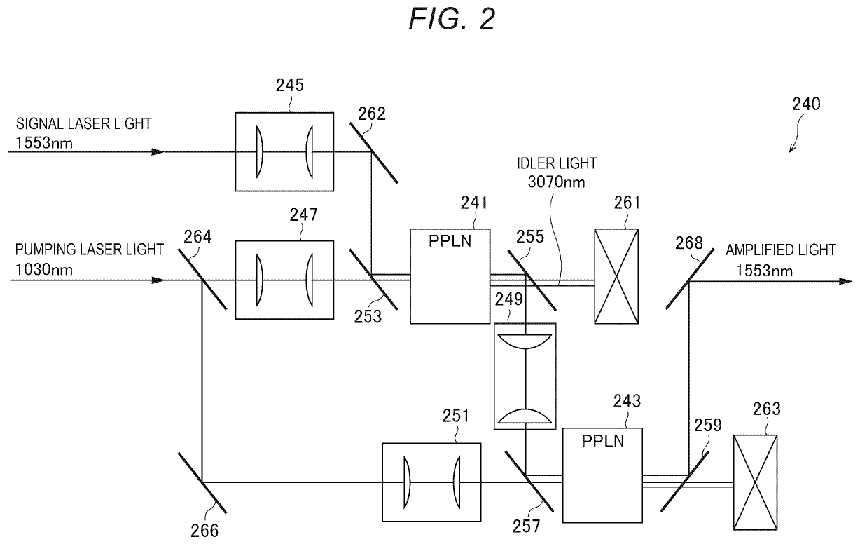

FIG. 2 schematically shows the configuration of the OPA 240. The OPA 240 includes PPLN crystals 241 and 243, beam diameter adjusting optical systems 245, 247, 249, and 251, DMs 253, 255, 257, and 259, dampers 261 and 263, optical-path-forming optical path mirrors 262, 266, and 268, and a beam splitter 264.

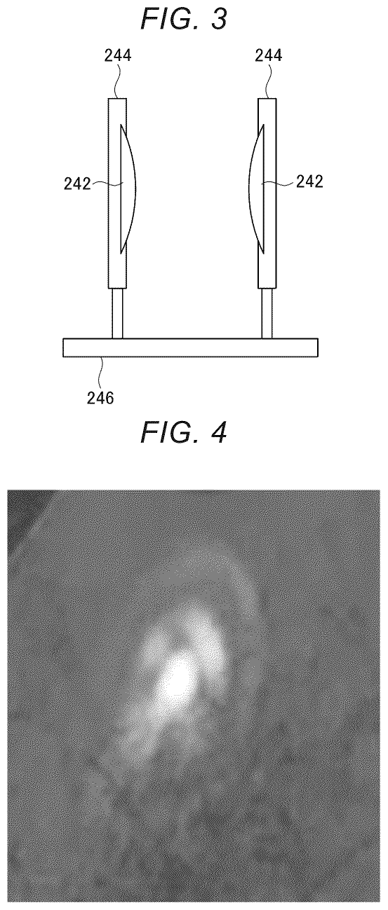

FIG. 3 schematically shows the configuration of the beam diameter adjusting optical system 245 of the OPA 240. The beam diameter adjusting optical system 245 includes multiple lenses 242 and 242. The lenses 242 and 242 are held by holders 244 and 244, respectively, and are disposed so as to face each other on a base plate 246. The beam diameter adjusting optical system 245 is configured to adjust the distance between the lenses 242 and 242. The other beam diameter adjusting optical systems 247, 249, and 251 may have the same configuration.

The beam diameter adjusting optical systems 245 and 247 are so configured that the beam waist diameters of the signal laser light and the pumping laser light to be incident on the PPLN crystal 241 are approximately the same in the crystal. The beam diameter adjusting optical system 245 is disposed in the optical path of the signal laser light, and the beam diameter adjusting optical system 247 is disposed in the optical path of the pumping laser light.

The beam diameter adjusting optical systems 249 and 251 are so configured that the beam waist diameters of the signal laser light and the pumping laser light to be incident on the PPLN crystal 243 are approximately the same in the crystal. The beam diameter adjusting optical system 249 is disposed in the optical path of the signal laser light between the PPLN crystals 241 and 243, and the beam diameter adjusting optical system 251 is disposed in the optical path of the pumping laser light.

The beam diameter adjusting optical systems 245, 247, 249, and 251 may each, for example, be configured to maintain the inter-lens distance between the pair of lenses 242, 242 facing each other (see FIG. 3). The beam diameter adjusting optical systems 245, 247, 249, and 251 can adjust the beam waist positions and beam waist diameters of the signal laser light and the pumping laser light.

The beam splitter 264 is disposed in the optical path of the pumping laser light so as to split the pumping laser light from the pumping laser apparatus 270 and cause the split pumping laser light to enter the beam diameter adjusting optical systems 247 and 251. The optical path mirror 266 is disposed so as to reflect the pumping laser light reflected off the beam splitter 264 to guide the reflected pumping laser light to the beam diameter adjusting optical system 251.

The DMs 253 and 257 are dichroic mirrors that combine the signal laser light and the pumping laser light with each other. For example, the DMs 253 and 257 each reflect light having the wavelength of about 1553 nm at high reflectance and transmit light having the wavelength of about 1030 nm at high transmittance.

The DMs 255 and 259 are dichroic mirrors that separate the pumping laser light and idler light from the light output from the PPLN crystals 241 and 243, respectively. For example, the DMs 255 and 259 each reflect light having the wavelength of about 1553 nm at high reflectance and transmit light having the wavelength of about 1030 nm and light having a wavelength of about 3070 nm at high transmittance.

The dampers 261 and 263 absorb the pumping laser light and the idler light separated by the DMs 255 and 259. The multiple optical path mirrors 262, 266, and 268 are disposed to constitute the optical paths of the OPA 240.

### 1.2.2 Operation

The signal laser light and the pumping laser light are incident on the PPLN crystal 241 via the beam diameter adjusting optical systems 245 and 247, respectively. At this point of time, the beam waist positions of the signal laser light and the pumping laser light that enter the PPLN crystal 241 coincide with each other, and the beam waist diameters of the two types of coaxially incident laser light are set at approximately the same value inside the PPLN crystal 241.

When the signal laser light and the pumping laser light enter the PPLN crystal 241, optical parametric amplification occurs in the PPLN crystal 241 to generate amplified light having the wavelength of approximately 1553 nm, which is the same as the wavelength of the signal laser light, and further generate the idler light having the wavelength of approximately 3070 nm corresponding to the difference in frequency between the signal laser light and the pumping laser light.

The pumping laser light and the idler light output from the PPLN crystal 241 are absorbed by the damper 261 via the DM 255. The light having the wavelength of about 1553 nm output from the PPLN crystal 241 and containing the amplified light and the signal laser light enters the PPLN crystal 243 via the DM 255, the beam diameter adjusting optical system 249, and the DM 257. The laser light having the wavelength of about 1553 nm output from the PPLN crystal 241 becomes the signal laser light to be input to the PPLN crystal 243.

The pumping laser light reflected off the beam splitter 264 enters the PPLN crystal 243 via the optical path mirror 266, the beam diameter adjusting optical system 251, and the DM 257. At this point of time, the beam waist diameters of the pumping laser light and the signal laser light are set at approximately the same value inside the PPLN crystal 243. Optical parametric amplification occurs in the PPLN crystal 243 to generate amplified light having the wavelength of approximately 1553 nm, which is the same as the wavelength of the signal laser light, and further generate idler light having the wavelength of approximately 3070 nm corresponding to the difference in frequency between the signal laser light and the pumping laser light.

The pumping laser light and the idler light output from the PPLN crystal 243 are absorbed by the damper 263 via the DM 259. The amplified light output from the PPLN crystal 243 is used by the CLBO crystal 285 of the wavelength conversion system 280 to perform the sum-frequency generation (see FIG. 1).

### 1.2.3 Effects and Advantages

The beam waist diameters of the pumping laser light and the signal laser light are adjusted to have approximately the same value inside each of the PPLN crystals 241 and 243. The reason for this is that the beam waists having the same diameter are set near the centers of the crystals in order to ensure a wide region where efficient phase matching is achieved at the beam waist positions where the beams are regarded as plane waves. As a result, the mode matching between the signal laser light and the pumping laser light is improved, so that intense amplified light can be produced.

### 2. Problems

In the amplification system 230 using the OPA 240, a multi-ring profile may occur depending on the conditions under which the signal light and the pumping light enter the crystals. For example, the light amplified by the OPA 240 may have a multi-ring profile under a specific condition. FIG. 4 shows amplified light having a multi-ring profile.

The amplified light having a multi-ring profile has poor light collectivity, and only about half the output from the OPA 240 can be used in some cases in the subsequent wavelength conversion and amplification. There has therefore been a demand for a laser system that prevents the light amplified by the OPA 240 from having a multi-ring profile.

### 3. First Embodiment

### 3.1 Configuration

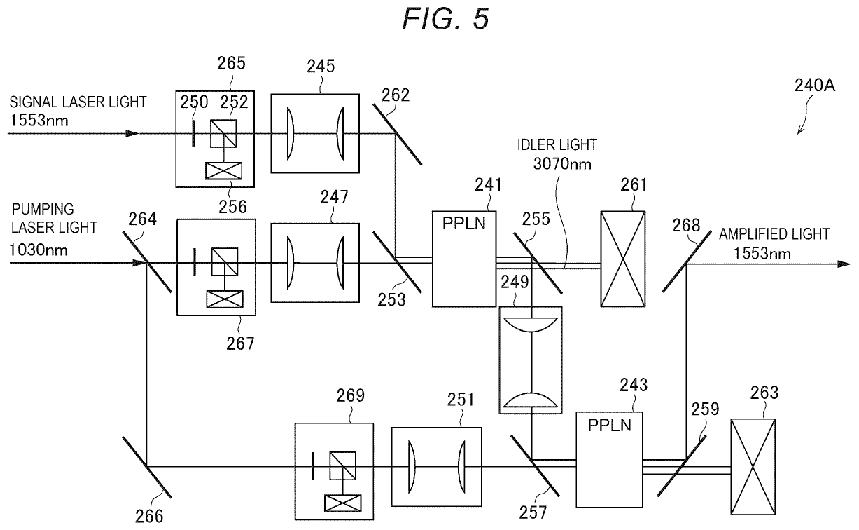

A laser system 20 according to a first embodiment includes an OPA 240A shown in FIG. 5 in place of the OPA 240 shown in FIG. 2. The other configurations may be the same as those in FIG. 1.

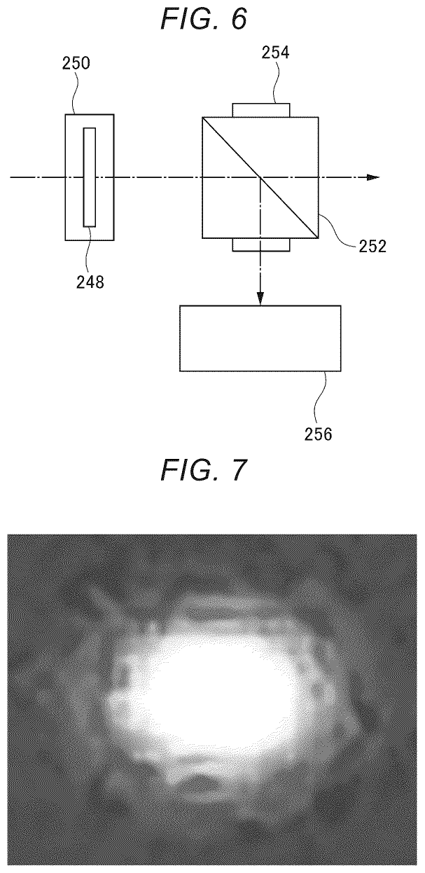

FIG. 5 schematically shows the configuration of the OPA 240A in the first embodiment. Differences in configuration between FIGS. 5 and 2 will be described. The OPA 240A includes beam power adjusting systems 265, 267, and 269. The beam power adjusting systems each include, for example, a 2/2 plate (HWP) 248, a polarizing beam splitter (PBS) 252, and a power meter 256 or a damper (see FIG. 6).

FIG. 6 schematically shows the configurations of the beam power adjusting systems 265, 267, and 269 of the OPA 240A in the first embodiment. The HWP 248 is held by a rotary holder 250 so as to be rotatable around the optical axis. The PBS 252 is held by a holder 254. The PBS 252 may be a cube-shaped PBS or a planar-plate-shaped PBS. The HWP 248 and the PBS 252 are disposed in this order in the optical path, and the power meter 256 or the damper is disposed in the reflected light optical path of the PBS 252.

The beam power adjusting systems 265 and 267 are disposed in the optical paths of the signal light and the pumping light, respectively, to be incident on the PPLN crystal 241, and adjust the power of the signal light and the pumping light, respectively, to be incident on the PPLN crystal 241. The signal light and the pumping light to be incident on the PPLN crystal 241 has a Gaussian light intensity distribution.

The beam power adjusting system 269 is disposed in the optical path of the pumping light to be incident on the PPLN crystal 243, and adjusts the power of the pumping light to be incident on the PPLN crystal 243.

The other configurations may be the same as those in FIG. 2.

### 3.2 Operation

In each of the beam power adjusting systems 265, 267, and 269, the HWP 248 can be rotated to adjust the polarized component passing through the PBS 252. In this process, the power of the polarized component reflected off the PBS 252 may be adjusted while being measured by the power meter 256, or the power meter 256 may be temporarily placed in the transmitted light optical path of the PBS 252 to adjust the power of the laser light passing through the PBS 252.

The sum of the photon flux densities of the signal light and the pumping light input to the PPLN crystals 241 and 243 is adjusted by the beam power adjusting systems 265, 267, and 269 and the beam diameter adjusting optical systems 245, 247, 249, and 251 so as to satisfy Expression (1) below at the beam center.

$${j}_{p} + {j}_{s} \leq \frac{2 {( c {ε}_{0} )}^{3}}{ℏ {d}_{eff}^{2} {L}^{2}} \frac{{n}_{p} {n}_{s} {n}_{i}}{{ω}_{p} {ω}_{s} {ω}_{i}} {\{ K ( \frac{1}{1 + \frac{{j}_{s}}{{j}_{p}}} ) \}}^{2} \qquad ( 1 )$$

The derivation of Expression (1) and the meaning of the symbols therein will be described later.

After the adjustment is completed, the angle of rotation of the HWP 248 may be fixed and the power meter 256 may be replaced with a damper, or the power meter 256 may be removed from the transmitted light optical path of the PBS 252.

The wavelength of about 1030 nm is an example of the “first wavelength” in the present disclosure, and the wavelength of about 1553 nm is an example of the “second wavelength” in the present disclosure. The PPLN crystals 241 and 243 are each an example of the “optical parametric crystal” in the present disclosure. The combination of the beam power adjusting systems 265 and 267 and the beam diameter adjusting optical systems 245 and 247 is an example of the “photon flux density control mechanism” in the present disclosure. The beam diameter adjusting optical system 245 is an example of the “first light collecting optical system” in the present disclosure, and the beam diameter adjusting optical system 247 is an example of the “second light collecting optical system” in the present disclosure. The beam power adjusting system 265 is an example of the “first power manipulator” in the present disclosure, and the beam power adjusting system 267 is an example of the “second power manipulator” in the present disclosure. The lenses 242 and 242 are an example of the “lens pair” in the present disclosure. The HWP 248 is an example of the “2/2 plate” in the present disclosure. The PBS 252 is an example of the “polarizing beam splitter” in the present disclosure. The semiconductor laser 271 is an example of the “first semiconductor laser” in the present disclosure. The solid-state amplifier 273 is an example of the “first solid-state amplifier” in the present disclosure. The LBO crystal 275 is an example of the “first nonlinear optical crystal” in the present disclosure. The semiconductor laser 211 is an example of the “second semiconductor laser” in the present disclosure. The solid-state amplifier 213 is an example of the “second solid-state amplifier” in the present disclosure. The CLBO crystal 281 is an example of the “second nonlinear optical crystal” in the present disclosure. The CLBO crystal 285 is an example of the “third nonlinear optical crystal” in the present disclosure. The CLBO crystal 287 is an example of the “fourth nonlinear optical crystal” in the present disclosure.

### 3.3 Derivation of Conditions

In plane wave approximation, a change in an optical electric field due to the nonlinear optical effect is expressed by Expressions (2) to (4) below (see Chapter 8, Section 4 of “OPTICAL ELECTRONICS: Advanced” by Yariv-Yeh (Maruzen Publishing), for example).

$$\frac{{dE}_{s}}{dz} = - \frac{i {ω}_{s}}{2 {n}_{s}} \sqrt{\frac{{μ}_{0}}{{ε}_{0}}} {d}_{eff} {E}_{p} {E}_{i}^{*} \qquad ( 2 )$$

$$\frac{{dE}_{s}}{dz} = - \frac{i {ω}_{i}}{2 {n}_{i}} \sqrt{\frac{{μ}_{0}}{{ε}_{0}}} {d}_{eff} {E}_{p} {E}_{s}^{*} \qquad ( 3 )$$

$$\frac{{dE}_{p}}{dz} = - \frac{i {ω}_{p}}{2 {n}_{p}} \sqrt{\frac{{μ}_{0}}{{ε}_{0}}} {d}_{eff} {E}_{s} {E}_{i} \qquad ( 4 )$$

In Expressions (1) to (4), the subscripts s, i, and p represent the signal light, the idler light, and the pumping light, respectively. When x is any complex number, x* represents the complex conjugate of x. The phase mismatch Δk is set at zero.

The meanings of the symbols are as follows:
c: the speed of light
ε₀: the permittivity in vacuum
μ₀: the permeability in vacuum
ℏ: the Planck constant/2π
ωₛ, ωᵢ, ωₚ: angular frequencies of the signal light, the idler light, and the pumping light
Eₛ, Eᵢ, Eₚ: complex amplitudes of electric fields of the signal light, the idler light, and the pumping light
Iₛ, Iᵢ, Iₚ: light intensities of the signal light, the idler light, and the pumping light
jₛ, jᵢ, jₚ: photon flux densities of the signal light, the idler light, and the pumping light
d_{eff}: an effective nonlinear constant of a nonlinear optical crystal
L: a crystal length of the nonlinear optical crystal
nₛ, nᵢ, nₚ: refractive indices of the nonlinear optical crystal at wavelengths of the signal light, the idler light, and the pumping light
z: position coordinates in a light propagation direction

Consider a case where the initial conditions of the OPA are E_{S}=E_{S,in}, Eᵢ=0, and Eₚ=E_{p,in} at z=0, and the solution of the differential equation is expressed by Expressions (5) to (9) below using Jacobi elliptic functions sn, cn, and dn.

$${E}_{s} ( z ) = {E}_{s , i n} \frac{1}{dn ( u \vert m )} \qquad ( 5 )$$

$${E}_{i} ( z ) = - i \sqrt{\frac{{n}_{s} {ω}_{i} {n}_{p}}{{ω}_{s} {n}_{i} {ω}_{p}}} \frac{{E}_{s , i n}^{*} {E}_{p , i n}}{\sqrt{\frac{{n}_{s}}{{ω}_{s}} {\vert {E}_{s , i n} \vert}^{2} + \frac{{n}_{p}}{{ω}_{p}} {\vert {E}_{p , i n} \vert}^{2}}} \frac{sn ( u \vert m )}{dn ( u \vert m )} \qquad ( 6 )$$

$${E}_{p} ( z ) = {E}_{p , i n} \frac{cn ( u \vert m )}{dn ( u \vert m )} \qquad ( 7 )$$

$$u = \frac{{d}_{eff} z}{2} \sqrt{\frac{{μ}_{0}}{{ε}_{0}} \frac{{ω}_{s} {ω}_{i} {ω}_{p}}{{n}_{s} {n}_{i} {n}_{p}}} \sqrt{\frac{{n}_{s}}{{ω}_{s}} {\vert {E}_{s , i n} \vert}^{2} + \frac{{n}_{p}}{{ω}_{p}} {\vert {E}_{p , i n} \vert}^{2}} \qquad ( 8 )$$

$$m = \frac{\frac{{n}_{p}}{{ω}_{p}} {\vert {E}_{p , i n} \vert}^{2}}{\frac{{n}_{s}}{{ω}_{s}} {\vert {E}_{s , i n} \vert}^{2} + \frac{{n}_{p}}{{ω}_{p}} {\vert {E}_{p , i n} \vert}^{2}} \qquad ( 9 )$$

The Jacobi elliptic functions sn, cn, and dn are defined by Expressions (10) to (12) below.

$$sn ( u \vert m ) = sin ( am ( u \vert m ) ) \qquad ( 10 )$$

$$cn ( u \vert m ) = cos ( am ( u \vert m ) ) \qquad ( 11 )$$

$$dn ( u \vert m ) = \sqrt{1 - m {sin}^{2} ( am ( u \vert m ) )} \qquad ( 12 )$$

The amplitude am is an inverse function of the elliptic integral of the first kind F, and satisfies Expression (14) below when Expression (13) below holds.

$$u = F ( ϕ \vert m ) \qquad ( 13 )$$

$$ϕ = am ( u \vert m ) \qquad ( 14 )$$

The elliptic integral of the first kind F is given by Expression (15) below when 0<m<1 holds.

$$F ( ϕ \vert m ) = {\int }_{0}^{ϕ} \frac{d θ}{\sqrt{1 - m {sin}^{2} θ}} \qquad ( 15 )$$

The relationship between the light intensity of the signal light Iₛ and the complex amplitude of the electric field of the signal light Eₛ is expressed by Expression (16) below.

$${I}_{s} = \frac{1}{2} \sqrt{\frac{{ε}_{0}}{{μ}_{0}}} {n}_{s} {\vert {E}_{s} \vert}^{2} \qquad ( 16 )$$

The relationship between the light intensity of the pumping light Iₚ and the complex amplitude of the electric field of the pumping light Eₚ is expressed by Expression (17) below.

$${I}_{p} = \frac{1}{2} \sqrt{\frac{{ε}_{0}}{{μ}_{0}}} {n}_{p} {\vert {E}_{p} \vert}^{2} \qquad ( 17 )$$

In particular, the light intensity of the output signal light I_{s,out} at z=L is expressed by Expressions (18) to (20) below using the light intensities of the signal light and pumping light I_{s,in} and I_{p,in} at z=0.

$${I}_{s , out} = {I}_{s , i n} \frac{1}{{dn}^{2} ( u \vert m )} \qquad ( 18 )$$

$$u = \frac{{d}_{eff} L}{\sqrt{2}} {( \frac{{μ}_{0}}{{ε}_{0}} )}^{\frac{3}{4}} \sqrt{\frac{{ω}_{i} {ω}_{i} {ω}_{p}}{{n}_{s} {n}_{i} {n}_{p}}} \sqrt{\frac{{I}_{s , i n}}{{ω}_{s}} + \frac{{I}_{p , i n}}{{ω}_{p}}} = \frac{{d}_{eff} L}{\sqrt{2 {( c {ε}_{0} )}^{2}}} \sqrt{\frac{{ω}_{s} {ω}_{i} {ω}_{p}}{{n}_{s} {n}_{i} {n}_{p}}} \sqrt{\frac{{I}_{s , i n}}{{ω}_{s}} + \frac{{I}_{p , i n}}{{ω}_{p}}} ( ∵ {μ}_{0} = \frac{1}{{c}^{2} {ε}_{0}} ) \qquad ( 19 )$$

$$m = \frac{\frac{{I}_{p , i n}}{{ω}_{p}}}{\frac{{I}_{s , i n}}{{ω}_{s}} + \frac{{I}_{p , i n}}{{ω}_{p}}} = \frac{1}{1 + \frac{{ω}_{p}}{{ω}_{s}} \frac{{I}_{s , i n}}{{I}_{p , i n}}} \qquad ( 20 )$$

Consider now a Gaussian beam near the beam waist as the input light. Approximation is made on the assumption that changes in the beam diameter of the input light can be ignored over the entire length of the crystal, and that results of the plane wave approximation calculation are applicable.

That is, the approximation is made on the assumption that the profile of the output light depends on the profile of the input light and is expressed by Expressions (21) to (23) below.

$${I}_{s , o u t} ( x , y ) = {I}_{s , i n} ( x , y ) \frac{1}{d {n}^{2} ( u ( x , y ) \vert m ( x , y ) )} \qquad ( 21 )$$

$$u ( x , y ) = \frac{{d}_{e f f} L}{\sqrt{2 {( c {ε}_{0} )}^{3}}} \sqrt{\frac{{ω}_{s} {ω}_{i} {ω}_{p}}{{n}_{s} {n}_{i} {n}_{p}}} \sqrt{\frac{{I}_{s , i n} ( x , y )}{{ω}_{s}} + \frac{{I}_{p , i n} ( x , y )}{{ω}_{p}}} \qquad ( 22 )$$

$$m = \frac{1}{1 + \frac{{ω}_{p}}{{ω}_{s}} \frac{{I}_{s , i n} ( x , y )}{{I}_{p , i n} ( x , y )}} \qquad ( 23 )$$

In Expressions (21) to (23), x and y are position coordinates set so as to be orthogonal to each other in a plane perpendicular to the light propagation direction z.

Expression (24) below has a period 2K(m) for u, increases when 0<u<K(m) holds, and decreases when K(m)<u<2K(m) holds.

$$1 / {dn}^{2} ( u \vert m ) \qquad ( 24 )$$

K is the complete elliptic integral of the first kind, and is expressed by Expression (25) below.

$$K ( m ) = {\int }_{0}^{π / 2} \frac{d θ}{\sqrt{1 - m {sin}^{2} θ}} \qquad ( 25 )$$

The light intensity of a Gaussian beam decreases from the center toward the periphery. Therefore, when the condition u≤K(m) can be satisfied at the beam center, the profile of the output light has a profile that decreases from the center toward the periphery, and it is believed that the occurrence of multi-ring profile can be prevented. FIG. 7 shows the light amplified by the OPA 240A and having a suppressed multi-ring profile. The intensity distribution of the light amplified by the OPA 240A monotonically decreases from the center toward the periphery, as shown in FIG. 7.

Since u≤K(m), it is preferable to satisfy Expression (26) below at the beam center.

$$\frac{{d}_{eff} L}{\sqrt{2 {( c {ε}_{0} )}^{3}}} \sqrt{\frac{{ω}_{p} {ω}_{s} {ω}_{i}}{{n}_{p} {n}_{s} {n}_{i}}} \sqrt{\frac{{I}_{p}}{{ω}_{p}} + \frac{{I}_{s}}{{ω}_{s}}} \leq K ( \frac{1}{1 + \frac{{ω}_{p}}{{ω}_{s}} \frac{{I}_{s}}{{I}_{p}}} ) \qquad ( 26 )$$

Expression (1) is derived by rearranging Expression (26) by using the photon flux densities jₛ and jₚ expressed by Expression (27) below.

$${j}_{s} / {I}_{s} / ( {ℏω}_{s} ) , {j}_{p} = {I}_{p} / ( {ℏω}_{p} ) \qquad ( 27 )$$

$${j}_{p} + {j}_{s} \leq \frac{2 {( c {ε}_{0} )}^{3}}{ℏ {d}_{eff}^{2} {L}^{2}} \frac{{n}_{p} {n}_{s} {n}_{i}}{{ω}_{p} {ω}_{s} {ω}_{i}} {\{ K ( \frac{1}{1 + \frac{{j}_{s}}{{j}_{p}}} ) \}}^{2} \qquad ( 1 )$$

### 3.4 Effects and Advantages

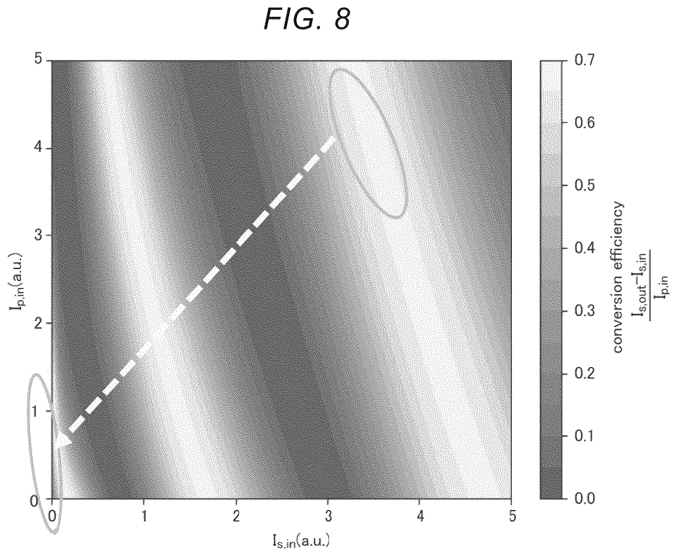

FIG. 8 is a graph showing amplified light conversion efficiency in the form of a heat map. In FIG. 8, the horizontal axis represents the intensity (arbitrary unit) of the input signal light, and the vertical axis represents the intensity (arbitrary unit) of the input pumping light. Note that the right portion of FIG. 8 shows a legend of the heat map along with the definition expression of the conversion efficiency. The expression of the conversion efficiency has a denominator being the intensity (arbitrary unit) of the input pumping light and a numerator being the difference as a result of subtraction of the intensity (arbitrary unit) of the input signal light from the intensity (arbitrary unit) of the output signal light.

For example, select the light intensity at the beam center in the upper right elliptical region of the graph shown in FIG. 8, and the input intensity weakens toward the outer periphery of the beam, and the conversion efficiency increases and decreases, resulting in a multi-ring profile (see FIG. 4).

In contrast, select the light intensity at the beam center in the lower left elliptical region of the graph shown in FIG. 8, and the conversion efficiency does not increase but decreases toward the outer periphery of the beam. The lower left elliptical region in FIG. 8 is a region where the condition expressed by Expression (1) is satisfied.

In the OPA 240A according to the first embodiment, the sum of the photon flux density of the input signal light and the photon flux density of the input pumping light is adjusted by the configuration shown in FIG. 5 so as to satisfy the condition expressed by Expression (1). As described above, the first embodiment allows generation of amplified light having a suppressed multi-ring profile.

To adjust the power of each of the signal light and the pumping light, it is conceivable to employ a configuration in which the output from each of the semiconductor laser 211 and the solid-state amplifier 213 is adjusted without relying on the beam power adjusting systems 265 and 267. In this case, however, the condition under which heat is input to the crystal of the solid-state amplifier 213 changes, so that there is a concern that the thermal lens effect of the crystal may change.

When the thermal lens effect of the crystal changes, the intensity distribution and divergence angle of the light amplified by the solid-state amplifier 213 may change. When the intensity distribution of the light amplified by the solid-state amplifier 213 changes, the profile of the light amplified by the OPA 240 also changes. When the divergence angle of the light amplified by the solid-state amplifier 213 changes, the beam waist position of each of the various types of input light in the OPA 240 changes, which may result in a decrease in the amplification efficiency.

To prevent the decrease, it is required to employ a configuration that allows adjustment of the power of the light amplified by the solid-state amplifier 213 while maintaining the intensity distribution and divergence angle of the amplified light. FIG. 5 shows one example of the configuration. Therefore, the power of the amplified light only needs to be adjusted with the intensity distribution and divergence angle thereof maintained, and a configuration in which the power is adjusted by inserting an ND filter or the like may be employed.

### 4. Second Embodiment

### 4.1 Configuration of Laser Processing System

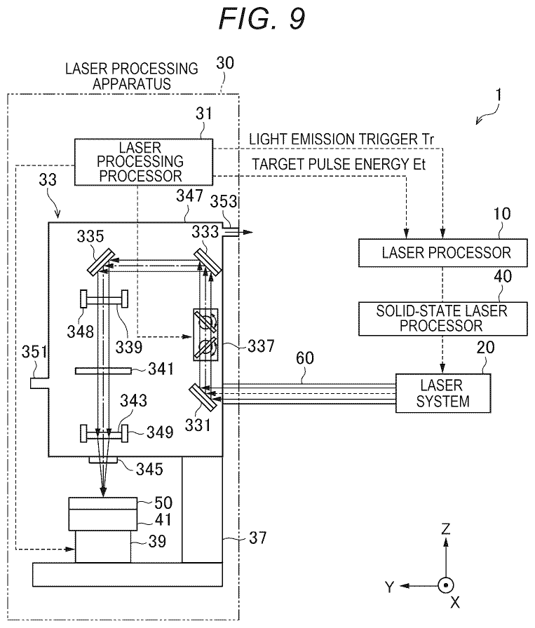

FIG. 9 schematically shows the configuration of a laser processing system 1 according to a second embodiment. The laser processing system 1 shown in FIG. 9 includes the laser processor 10, the laser system 20, a laser processing apparatus 30, the solid-state laser processor 40, and an optical path tube 60. The laser processing system 1 may be used to drill holes in an interposer glass plate.

The laser processing apparatus 30 includes a laser processing processor 31, a radiation optical system 33, a frame 37, an XYZ stage 39, and a table 41, at which a radiation receiving object 50 is placed.

The radiation optical system 33 includes highly reflective mirrors (HM) 331, 333, and 335, an attenuator 337, an illumination optical system 339, a photomask 341, a projection optical system 343, a window 345, and an enclosure 347.

The HMs 331, 333, and 335 are fixed to respective holders that are not shown in the enclosure 347, and are so arranged that the laser light output from the laser system 20 enters the illumination optical system 339.

The attenuator 337 is disposed in the optical path between the HM 331 and the HM 333. The attenuator 337 includes two partially reflective mirrors that are not shown and rotary stages that are not shown but are capable of changing the angles of incidence of light incident on the partially reflective mirrors.

The illumination optical system 339 is fixed to a holder 348 and disposed so as to illuminate the photomask 341 with light in the form of Koehler illumination.

The photomask 341 is, for example, a mask including a synthetic quartz substrate which transmits ultraviolet light and at which a patterned metal or dielectric multilayer film is formed.

The projection optical system 343 is fixed to a holder 349 and is so disposed that the beam waist position of the collected laser light through the window 345 can be located at a predetermined depth ΔZsfw in the radiation receiving object 50 from the light-incident-side surface thereof. The projection optical system 343 may be a single lens or an aberration corrected lens assembly.

The window 345 is located in the optical path between the projection optical system 343 and the radiation receiving object 50, and disposed in a hole of the enclosure 347, for example, via an O-ring that is not shown.

The enclosure 347 is provided with an inlet 351 and an outlet 353, via which an N₂ gas is introduced and discharged, and is sealed, for example, with an O-ring that is not shown to prevent outside air from entering the enclosure 347.

The radiation optical system 33 and the XYZ stage 39 are fixed to the frame 37, and the table 41 is disposed on the XYZ stage 39. The radiation receiving object 50 is fixed onto the table 41. The radiation receiving object 50 used to manufacture an interposer may, for example, be a glass substrate made of quartz glass or any other suitable material.

The space between the window 345 and the radiation receiving object 50 is filled with are.

The optical path tube 60 is disposed between the laser system 20 and the radiation optical system 33, and is sealed, for example, with an O-ring that is not shown. The interior of the optical path tube 60 is also purged with an N₂ purge gas.

### 4.2 Operation of Laser Processing System

The laser processing processor 31 controls the position of the radiation receiving object 50 by using the XYZ stage 39 in such a way that the beam waist of the laser light collected by the radiation optical system 33 is located at the predetermined depth within the radiation receiving object 50 from the surface thereof and the collected light has a predetermined diameter.

The laser processing processor 31 then transmits target pulse energy Et to the laser processor 10 to control transmittance T of the attenuator 337 to achieve target fluence Fm at the radiation receiving object 50.

The laser processing processor 31 transmits a light emission trigger signal Tr having a predetermined number of pulses Nm at a predetermined repetition frequency fm to the laser processor 10.

Upon reception of the light emission trigger signal Tr, the laser processor 10 controls the laser system 20 in such a way that the target pulse energy Et is achieved.

The laser processor 10 causes the laser system 20 to output the laser light in synchronization with the light emission trigger signal Tr, and the laser light enters the laser processing apparatus 30.

The laser light is reflected off the HM 331 at high reflectance, passes through the attenuator 337 at the transmittance T, and is incident on the HM 333.

The laser light reflected off the HM 333 at high reflectance enters the illumination optical system 339 via the HM 335.

The laser light having passed through the illumination optical system 339 passes through the window 345 and is collected at the predetermined depth within the radiation receiving object 50 from the light-incident-side surface thereof.

As a result, the laser light is radiated at the predetermined depth in the radiation receiving object 50 under the conditions that the fluence is Fm, the repetition frequency is fm, and the number of pulses is Nm, and a hole is drilled with the laser light.

Note that the laser processor 10, the laser processing processor 31, and the solid-state laser processor 40 may be provided independently from one another, and any one of the processors may instead have all the functions of the three processors. Furthermore, a unit having the functions of the laser processor 10, the laser processing processor 31, and the solid-state laser processor 40 may be simply referred to as a processor.

### 5. Method for Manufacturing Electronic Device Including Interposer

### 5.1 Example of Configuration of Electronic Device

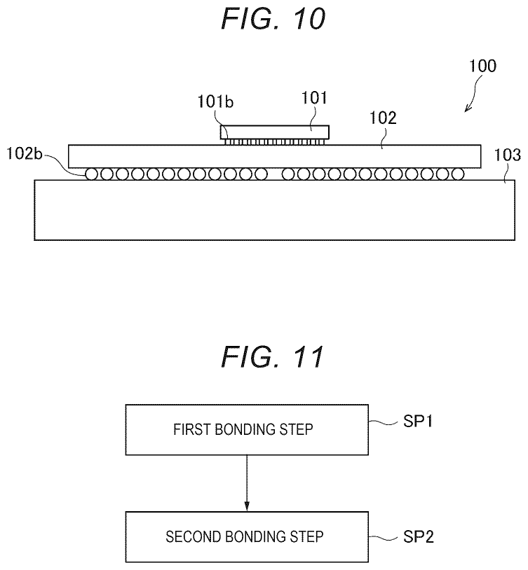

FIG. 10 diagrammatically shows the configuration of an electronic device 100. The electronic device 100 shown in FIG. 10 includes an integrated circuit chip 101, an interposer 102, and a circuit substrate 103. The integrated circuit chip 101 is, for example, a chip-shaped integrated circuit substrate that is a silicon substrate in which an integrated circuit is formed. The integrated circuit chip 101 is provided with multiple bumps 101b electrically connected to the integrated circuit.

The interposer 102 includes an insulating glass substrate having multiple through holes formed therein, and a conductor that electrically connects the front and rear sides of the glass substrate to each other is provided in each of the through holes.

Multiple lands to be connected to the bumps 101b provided at the integrated circuit chip 101 are formed at one surface of the interposer 102, and the lands are each electrically connected to the conductor in any of the through holes. Multiple bumps 102b are provided at the other surface of the interposer 102, and the bumps 102b are each electrically connected to the conductor in any of the through holes.

Multiple lands to be connected to the respective bumps 102b are formed at one surface of the circuit substrate 103. The circuit substrate 103 includes multiple terminals to be electrically connected to the lands.

### 5.2 Electronic Device Manufacturing Method

FIG. 11 is a flowchart showing a method for manufacturing the electronic device 100. The method for manufacturing the electronic device 100 in the present description includes a first bonding step SP1 and a second bonding step SP2, as shown in FIG. 11.

In the first bonding step SP1, the integrated circuit chip 101 is bonded to the interposer 102. Specifically, the bumps 101b of the integrated circuit chip 101 are placed on the respective lands of the interposer 102, so that the bumps 101b are electrically connected to the lands. The integrated circuit chip 101 is thus electrically connected to the interposer 102.

In the second bonding step SP2, the interposer 102 is bonded to the circuit substrate 103. Specifically, the bumps 102b of the interposer 102 are placed on the respective lands of the circuit substrate 103, so that the bumps 102b are electrically connected to the lands. The integrated circuit chip 101 is thus electrically connected to the circuit substrate 103 via the interposer 102. The electronic device 100 is manufactured through the steps described above.

### 6. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser system comprising:
a pumping laser apparatus configured to output pumping light having a first wavelength;
a signal laser apparatus configured to output signal light having a second wavelength longer than the first wavelength;
an optical parametric crystal configured to transmit the pumping light and the signal light and output amplified light having the second wavelength; and
a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

2. The laser system according to claim 1, wherein
the photon flux density control mechanism includes
a first light collecting optical system configured to adjust a beam diameter of the signal light,
a second light collecting optical system configured to adjust a beam diameter of the pumping light,
a first power manipulator configured to adjust power of the signal light, and
a second power manipulator configured to adjust power of the pumping light.

3. The laser system according to claim 2, wherein
the first and second light collecting optical systems each include a lens pair configured to adjust an inter-lens distance, and
each of the first and second power manipulators includes a λ/2 plate and a polarizing beam splitter and is configured to adjust an angle of rotation of the λ/2 plate around an optical axis thereof.

4. The laser system according to claim 1, wherein
the pumping light and the signal light each have a Gaussian light intensity distribution.

5. The laser system according to claim 1, wherein
controlling the photon flux densities of the pumping light and the signal light includes controlling the photon flux densities of the pumping light and the signal light in such a way that a sum of the photon flux densities of the pumping light and the signal light satisfies a condition determined by the optical parametric crystal, the pumping light, the signal light, and idler light.

6. The laser system according to claim 5, wherein
the condition is determined by
a crystal length of the optical parametric crystal,
an effective nonlinear constant of the optical parametric crystal,
a refractive index of the optical parametric crystal at each of a wavelength of the pumping light, a wavelength of the signal light, and a wavelength of the idler light,
an angular frequency of each of the pumping light, the signal light, and the idler light, and
a beam light intensity at a beam center of each of the pumping light, the signal light, and the idler light in the optical parametric crystal.

7. The laser system according to claim 1, wherein
the photon flux densities of the pumping light and the signal light satisfy an expression below,
$${j}_{p} + {j}_{s} \leq \frac{2 {( c {ε}_{0} )}^{3}}{ℏ {d}_{eff}^{2} {L}^{2}} \frac{{n}_{p} {n}_{s} {n}_{i}}{{ω}_{p} {ω}_{s} {ω}_{i}} {\{ K ( \frac{1}{1 + \frac{{j}_{s}}{{j}_{p}}} ) \}}^{2}$$
where subscripts s, i, and p represent the signal light, idler light, and the pumping light, respectively,
c: a speed of light,
ε₀: a permittivity in vacuum,
ℏ: a Planck constant/2π,
ωₛ, ωᵢ, ωₚ: angular frequencies of the signal light, the idler light, and the pumping light,
jₛ, jₚ: photon flux densities of the signal light and the pumping light,
d_{eff}: an effective nonlinear constant of a nonlinear optical crystal,
L: a crystal length of the nonlinear optical crystal,
nₛ, nᵢ, nₚ: refractive indices of the nonlinear optical crystal at wavelengths of the signal light, the idler light, and the pumping light, and
K: a complete elliptic integral of a first kind.

8. The laser system according to claim 1, wherein
the pumping laser apparatus includes
a first semiconductor laser, a first solid-state amplifier, and a first nonlinear optical crystal.

9. The laser system according to claim 1, wherein
the signal laser apparatus includes
a second semiconductor laser and a second solid-state amplifier.

10. The laser system according to claim 1, further comprising
a wavelength conversion system configured to convert a wavelength of the amplified light output from the optical parametric crystal and having the second wavelength.

11. The laser system according to claim 10, wherein
the wavelength conversion system is configured to
receive the amplified light output from the optical parametric crystal and having the second wavelength and ultraviolet light and output light as a result of sum-frequency generation performed on the amplified light and the ultraviolet light.

12. The laser system according to claim 10, wherein
the wavelength conversion system includes
a second nonlinear optical crystal, a third nonlinear optical crystal, and a fourth nonlinear optical crystal arranged in series.

13. A laser processing method comprising:
generating laser light having a second wavelength by using a laser system, and converting the second wavelength of the laser light having to generate ultraviolet laser light; and
irradiating a radiation receiving object with the ultraviolet laser light to process the radiation receiving object,
the laser system including
a pumping laser apparatus configured to output pumping light having a first wavelength,
a signal laser apparatus configured to output signal light having the second wavelength longer than the first wavelength,
an optical parametric crystal configured to transmit the pumping light and the signal light and output amplified light having the second wavelength, and
a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.

14. The laser processing method according to claim 13, wherein
the photon flux density control mechanism includes
a first light collecting optical system configured to adjust a beam diameter of the signal light,
a second light collecting optical system configured to adjust a beam diameter of the pumping light,
a first power manipulator configured to adjust power of the signal light, and
a second power manipulator configured to adjust power of the pumping light.

15. The laser processing method according to claim 14, wherein
the first and second light collecting optical systems each include a lens pair configured to adjust an inter-lens distance, and
each of the first and second power manipulators includes a λ/2 plate and a polarizing beam splitter and is configured to adjust an angle of rotation of the λ/2 plate around an optical axis thereof.

16. The laser processing method according to claim 14, wherein
controlling the photon flux densities of the pumping light and the signal light includes controlling the photon flux densities of the pumping light and the signal light in such a way that a sum of the photon flux densities of the pumping light and the signal light satisfies a condition determined by the optical parametric crystal, the pumping light, the signal light, and idler light.

17. The laser processing method according to claim 16, wherein
the condition is determined by
a crystal length of the optical parametric crystal,
an effective nonlinear constant of the optical parametric crystal,
a refractive index of the optical parametric crystal at each of a wavelength of the pumping light, a wavelength of the signal light, and a wavelength of the idler light,
an angular frequency of each of the pumping light, the signal light, and the idler light, and
a beam light intensity at a beam center of each of the pumping light, the signal light, and the idler light in the optical parametric crystal.

18. The laser processing method according to claim 16, wherein
the photon flux densities of the pumping light and the signal light are controlled so as to satisfy an expression below,
$${j}_{p} + {j}_{s} \leq \frac{2 {( c {ε}_{0} )}^{3}}{ℏ {d}_{eff}^{2} {L}^{2}} \frac{{n}_{p} {n}_{s} {n}_{i}}{{ω}_{p} {ω}_{s} {ω}_{i}} {\{ K ( \frac{1}{1 + \frac{{j}_{s}}{{j}_{p}}} ) \}}^{2}$$
where subscripts s, i, and p represent the signal light, idler light, and the pumping light, respectively,
c: a speed of light,
ε₀: a permittivity in vacuum,
ℏ: a Planck constant/2π,
ωₛ, ωᵢ, ωₚ: angular frequencies of the signal light, the idler light, and the pumping light,
jₛ, jₚ: photon flux densities of the signal light and the pumping light,
d_{eff}: an effective nonlinear constant of a nonlinear optical crystal,
L: a crystal length of the nonlinear optical crystal,
nₛ, nᵢ, nₚ: refractive indices of the nonlinear optical crystal at wavelengths of the signal light, the idler light, and the pumping light, and
K: a complete elliptic integral of a first kind.

19. An interposer manufacturing method comprising:
generating laser light having a second wavelength by using a laser system, and converting the second wavelength of the laser light having to generate ultraviolet laser light; and
irradiating a radiation receiving object with the ultraviolet laser light in order to manufacture an interposer,
the laser system including
a pumping laser apparatus configured to output pumping light having a first wavelength,
a signal laser apparatus configured to output signal light having the second wavelength longer than the first wavelength,
an optical parametric crystal configured to transmit the pumping light and the signal light and output amplified light having the second wavelength, and
a photon flux density control mechanism configured to control photon flux densities of the pumping light and the signal light in such a way that a sum of the photon flux densities of the pumping light and the signal light at an input end of the optical parametric crystal causes an intensity distribution of the amplified light having the second wavelength to be an intensity distribution that monotonously decreases from a center of the intensity distribution toward a periphery thereof.
